(19) United States
(12) Patent Application Publication
(10) Pub. No.: US 2006/0163734 A1
(43) Pub. Date: Jul. 27, 2006

(54) Fuse structure and method for making the same

(75) Inventors: Kong-Beng Thei, Hsin-Chu (TW); Chung-Long Cheng, Hsin-Chu (TW); Chung-Shi Liu, Hsin-Chu (TW); Harry Chuang, Austin, TX (US)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/041,585

(22) Filed: Jan. 24, 2005

(51) Int. Cl. H01L 23/48

(52) U.S. Cl. 257/758

(57) ABSTRACT

Provided are a fuse structure and a method for manufacturing the fuse structure. In one example, the method includes providing a multilayer interconnect structure (MLI) over a semiconductor substrate. The MLI includes multiple fuse connection and bonding connection features. A passivation layer is formed over the MLI and patterned to form openings, with each opening being aligned with one of the fuse connection or bonding connection features. A conductive layer is formed on the passivation layer and in the openings. The conductive layer is patterned to form bonding features and fuse structures. Each bonding feature is in contact with one of the bonding connection features, and each fuse structure is in contact with two of the fuse connection features. A cap dielectric layer is formed over the fuse structures and patterned to expose at least one of the bonding features while leaving the fuse structures covered.

### BACKGROUND

Laser programmable memory redundancy structures have been widely used in large scale memory devices to increase yield through the replacement of defective elements with spare rows and columns. However, the laser repair rate in current structures is low, in part because the processes used to control laser repair are too complicated. Furthermore, as semiconductor technology is scaled down to deep submicron levels, copper damascene processes have been implemented in multilayer interconnects. Copper has a relatively high current density tolerance and may be hard to vaporize using a laser. In addition, the integration of low-K material into multilayer dielectrics may cause cracking when fuses are etched during laser repair processing.

### BRIEF DESCRIPTION OF THE DRAWINGS

FIGS. 1-4 are sectional views of one embodiment of a fuse structure during various stages of fabrication.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

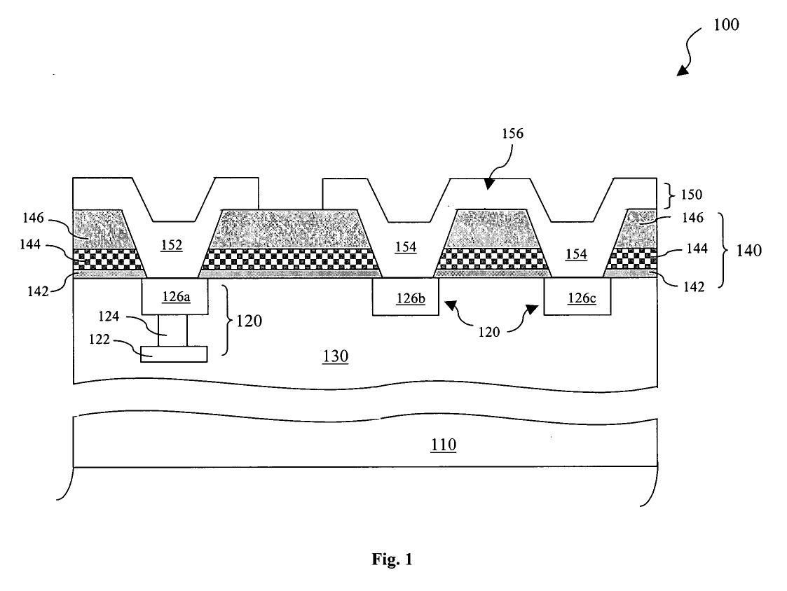

Referring to FIG. 1, in one embodiment, illustrated is a sectional view of an integrated circuit 100 having a fuse structure. The integrated circuit 100 includes a substrate 110. The substrate 110 may comprise one of a variety of semiconductor types, such as an elementary semiconductor, a compound semiconductor, or an alloy semiconductor. For example, an elementary semiconductor such as silicon, germanium, or diamond may be used, or the substrate 110 may comprise a compound semiconductor such as silicon carbide, gallium arsenic, indium arsenide, or indium phosphide. The substrate 110 may comprise an alloy semiconductor such as silicon germanium, silicon germanium carbide, gallium arsenic phosphide, and gallium indium phosphide. The substrate 110 may include an epitaxial layer. For example, the substrate may have an epitaxial layer overlying a bulk semiconductor. Furthermore, the substrate may be strained for performance enhancement. For example, the epitaxial layer may comprise semiconductor materials different from those of the bulk semiconductor, such as a layer of silicon germanium overlaying a bulk silicon layer, or a layer of silicon overlaying a bulk silicon germanium layer. In some examples, the substrate 110 may include a buried layer such as a buried oxide (BOX) layer in semiconductor-on-insulator (SOI) structure, an N-type buried layer, and/or a P-type buried layer.

The substrate 110 may include a plurality of semiconductor devices formed within or on the substrate. The plurality of semiconductor devices may include a plurality of memory cells such as static random-access-memory (SRAM), dynamic random-access-memory (DRAM), magnetic random-access-memory (MROM), non-volatile-memory (NVM), and/or combinations thereof. The NVM may further include programmable read-only-memory (PROM), phase-change-memory, and flash memory. The plurality of semiconductor devices may further include, but are not limited to, passive components such as resistors, capacitors, and inductors, active components such as metal-oxide-semiconductor field effect transistors (MOSFETs), bipolar transistors, high voltage transistors, high frequency transistors, or combinations thereof. The plurality of semiconductor devices may be isolated from each other by isolation features based on structures incorporating junction isolation, field isolation, and dielectric isolation such as local oxidation of silicon (LOCOS) and shallow trench isolation (STI).

The plurality of semiconductor devices in the substrate are electrically connected to form functional circuits and/or memory arrays and are also routed to power lines and input/output pads through a multilayer interconnect structure 120 (interconnect) formed on the substrate 110. The multilayer interconnect structure 120 may include contact/via features, such as an exemplary via 124, for vertical interconnections, and multilayer metal lines, such as an exemplary metal feature 122 and top metal features 126a, 126b, and 126c, for lateral interconnections. The metal features 122 and 126a through 126c may have further lateral and/or vertical connections. The thickness of each metal layer may vary. As an example, the top metal layer may have a thickness ranging from 8000 angstroms to about 12000 angstroms. The other metal layers may each have a thickness ranging from about 2000 angstroms to about 6000 angstroms. The interconnect 120 may comprise copper, copper alloy, titanium, titanium nitride, tantalum, tantalum nitride, tungsten, polysilicon, metal silicide, or combinations thereof as used for deep submicron processes. The metal silicide may be used to form contact features and may include nickel silicide, cobalt silicide, tungsten silicide, tantalum silicide, titanium silicide, platinum silicide, erbium silicide, palladium silicide, or combinations thereof. The multilayer interconnect may be formed using a dual damascene process including chemical vapor deposition (CVD), physical vapor deposition (PVD), atomic layer deposition (ALD), plating, or combinations thereof. It is understood that the metal features shown in FIG. 1 are meant for purposes of illustration, and that more or fewer features may be employed.

The integrated circuit 100 further includes an inter-metal dielectric (ILD) 130 formed in the multilayer interconnection 120. The ILD 130 may be used to fill spaces in the multilayer interconnection 120 and electrically separate each feature therein. The ILD 130 may comprise materials such as silicon oxide, fluorinated silica glass (FSG), carbon doped silicon oxide, silicon nitride, silicon oxynitride, low dielectric-constant (K) material, and combinations thereof. The low-k material may include Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and other materials. The low-k material may be used to decrease the dielectric constant, reduce RC delay, and enhance device performance. The ILD 130 may be formed by CVD, PVD, ALD, spin-on polymer (SOP), and/or other suitable processes. The ILD 130 may have multiple layers and may include a plurality of etch stop layers as appropriate for dual damascene processing.

A passivation structure 140 is formed above the top metal layer of the multilayer interconnection 120 for protecting the integrated circuit 100 from environmental degradations such as moisture penetration. The passivation structure 140 may comprise a multilayer structure formed of silicon oxide, silicon nitride, silicon oxynitride, and/or other suitable materials. An exemplary passivation structure 140 may include a layer of silicon nitride 142 having a thickness ranging from about 300 angstroms to about 1000 angstroms, a layer of silicon oxide 144 having a thickness ranging from about 3000 angstroms to about 5000 angstroms disposed over the layer of silicon nitride 142, and another layer of silicon nitride 146 having a thickness ranging from about 5000 angstroms to about 7000 angstroms positioned over the layer of silicon oxide 144. The passivation structure 140 is patterned to have a plurality of openings exposing at least some of the underlying metal features. In some embodiments, some or all of the openings may have sloped sidewalls. Each of the openings of the passivation layer 140 is aligned with a metal feature for bonding (e.g., the top metal feature 126a), or aligned with a metal feature for a fuse connection (e.g., the top metal features 126b and 126c). The passivation layer 140 may be formed by a multi-step process including chemical vapor deposition (CVD). For example, the passivation layer may be formed by a multiple-step plasma enhanced chemical vapor deposition (PECVD) process.

A conductive layer 150 is positioned over the passivation layer 140 and the metal features in the plurality of openings of the passivation layer. The conductive layer 150 may be formed so as to conform to the passivation layer and its plurality of openings and is in electrical contact with the underlying metal features 126a-126c through the plurality of openings. The conductive layer 150 may have a multilayer structure. The conductive layer 150 may be patterned by an etching process to define an exemplary bonding region 152 (electrically coupled to the top metal feature 126a) and an exemplary fuse region 154 (electrically coupled to the top metal features 126b and 126c). The conductive layer 150 may comprise aluminum, copper, aluminum copper alloy, and/or other conductive materials. In another example, the conductive layer 150 may comprise chromium, copper, gold, or combinations thereof. In still other examples, the conductive layer 150 may comprise copper, titanium, titanium nitride, tungsten, and combinations thereof. The conductive layer 150 may be formed by processes such as electroplating and physical vapor deposition (PVD). The bonding region 152 may comprise a redistribution layer (RDL) structure, an underbump metallization, and/or bonding pads. The fuse region 154 may include a fuse link portion 156 positioned over a portion of the passivation layer and between two openings thereof, each of the two openings being aligned with one of the top metal features 126b and 126c.

On the upper surface of the passivation layer 140, the conductive layer 150 may have a thickness ranging from about 0.5 micrometers to about 3 micrometers. The conductive layer 150 may have a multiple-thickness structure formed by a conventional patterning method using photolithography and etching processes. In one embodiment, the bonding region 152 may have a first thickness and the fuse region 154 may have a second thickness. For example, the bonding region 152 may have a thickness ranging from about 1.5 micrometers to about 3 micrometers, while the fuse link portion 156 may have a thickness ranging from about 3000 angstroms to about 8000 angstroms such that the fuse link portion 156 may reach a high enough temperature to be evaporated during subsequent laser fuse repair processing.

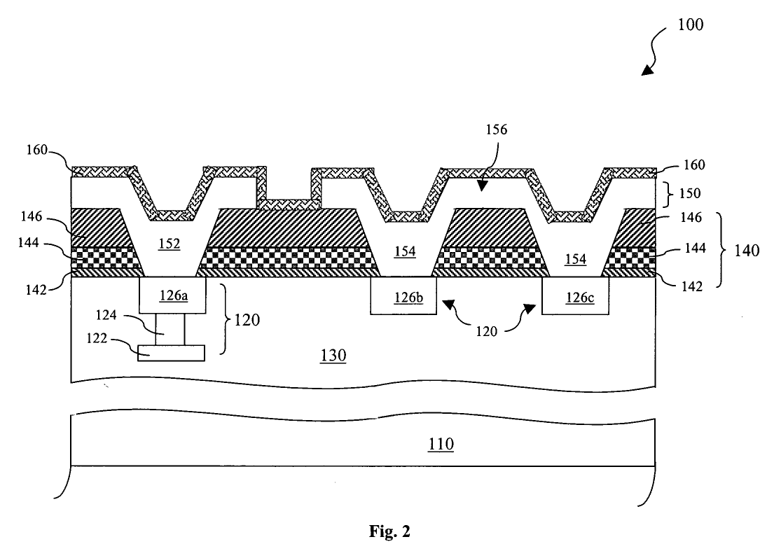

Referring to FIG. 2, illustrated is a sectional view of the integrated circuit 100 having a cap layer 160 formed over the conductive layer 150. The cap layer 160 may comprise silicon oxide, silicon nitride, combinations thereof, and/or other materials. The cap layer 160 may have a thickness ranging from about 1000 angstroms to about 2000 angstroms. An exemplary thickness of the cap layer 160 is 1500 angstroms. In general, the cap layer 160 may comprise a material that is translucent or transparent to a laser beam so that the laser beam may be directed through the cap layer to reach the underlying fuse structure during laser fuse repair processing. The thickness and strength of the cap layer 160 may be selected from a predefined range to ensure that the laser fuse repair processing will work properly. The cap layer 160 may also function as a protective and passivation layer for underlying structures. For example, the cap layer 160 may seal the underlying fuse structures to prevent moisture damage.

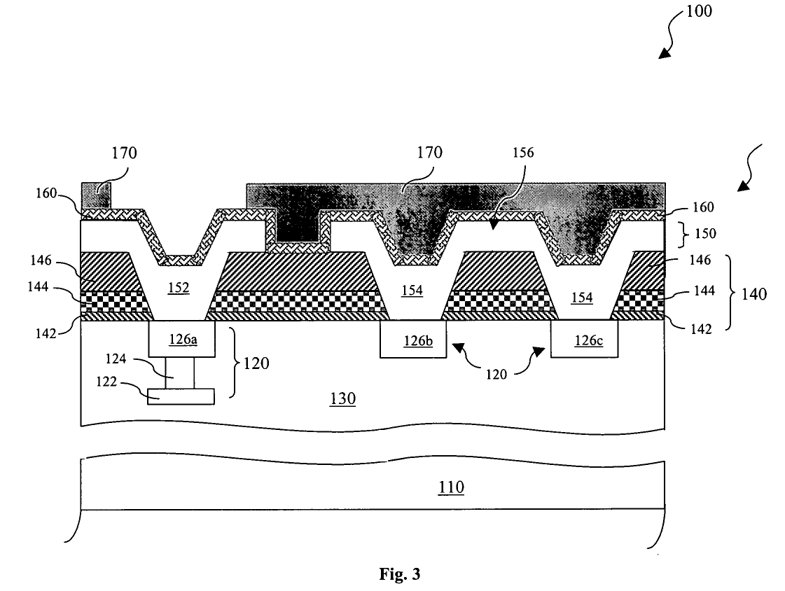

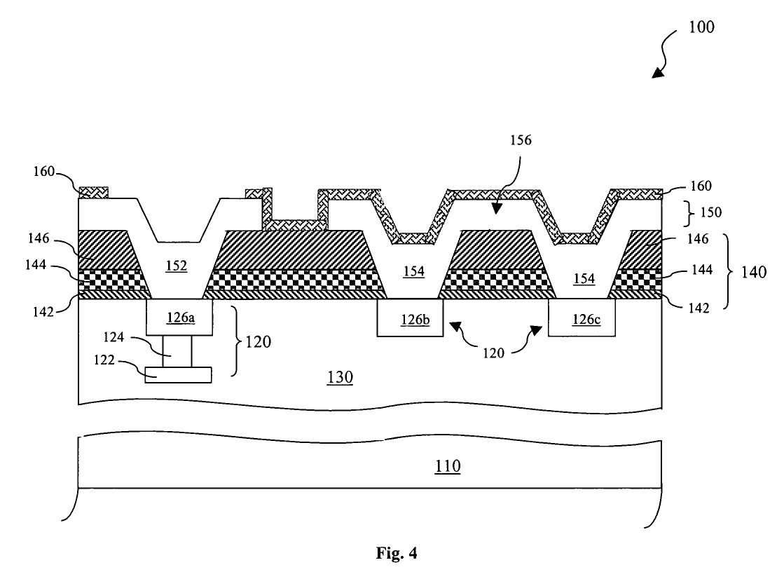

Referring to FIGS. 3 and 4, illustrated are sectional views of the integrated circuit 100 where the cap layer 160 is patterned using photolithography and etching processes. For example, the cap layer 160 may be etched to expose the bonding region 152 for further bonding processing. As illustrated in FIG. 3, in the photolithography process, a layer of photoresist 170 is formed on the integrated circuit 100 and then developed to have one or more openings that expose underlying portions of the cap layer 160. The exposed portions of the cap layer 160 are then removed to expose underlying features (e.g., the bonding region 152).

An exemplary photolithography process may include photoresist patterning, etching, and photoresist stripping. The photoresist patterning may further include processing steps such as photoresist coating, soft baking, mask aligning, exposing, post-exposure baking, developing, and hard baking. The etching process to remove the cap layer may include wet etching, dry etching, ion-reactive-etching (RIE), and other suitable processes. The cap layer 160 may be etched in multiple sub-steps. For example, a silicon oxide portion of the cap layer 160 may be removed by hydrofluoric (HF) acid or buffered hydrofluoric (BHF) acid, while a silicon nitride portion may be removed by phosphoric acid. A cleaning process may follow thereafter. It is understood that the photolithography process may also be implemented or replaced by other methods such as maskless photolithography, electron-beam writing, ion-beam writing, and molecular imprinting.

A laser fuse repair process may be implemented to reroute memory cells for replacing defective memory cells with redundant memory cells. For example, when a laser beam shines through the cap layer 160 to reach the underlying fuse link portion 156, the portion of the cap layer overlying the fuse is blown away and the fuse link portion is evaporated, resulting in a disconnect between the metal features 126b and 126c. Since the fuse region 154 is disposed in the conductive layer 150 above the multilayer interconnect structure, low-K film cracking and other undesirable issues may be minimized or eliminated. Furthermore, since the fuse structure is formed in a single process in conjunction with the bonding pads, and the cap dielectric layer is formed with an easily controllable thickness, the manufacturing process for the integrated circuit 100 is simplified.

In other embodiments, processing of the fuse region 154 may not be limited to laser trimming and the fuse region may be designed with dimensions for other trimming processes, such as processing using electric current and voltage. For example, when a potential is applied across metal features 126b and 126c, a current flows from metal feature 126b to the fuse region 154 (which has a small cross-sectional area compared to the metal features 126b and 126c), and then to metal feature 126c. Due to the small cross-sectional area of the fuse link portion 156, a phenomenon known as electromigration occurs. Electromigration describes the migration of atoms in the fuse link portion 156 due to momentum transfer from the electrons, which move in the applied electric field, to the ions which make up the lattice of the metal. A result of electromigration is failure of the metal in the fuse link portion 156, which causes a discontinuity or open circuit therein. Material of fuse link portion 156 and its method of fabrication are preferably selected so that failure caused by electromigration in the fuse link portion occurs at a desired level of current flow and applied voltage.

The application of the fuse structure is not limited to programmable redundancy for embedded memory circuits, and can be extended to other circuits that may need interconnection routing processing after completion of fabrication. For example, programmable gate arrays may use the fuse structure of the present disclosure.

The bonding region 152 may be connected using different methods for various purposes. For example, the bonding region 152 may be connected to a chip package using wire bonding, or may be connected to a patterned tape using tape automated bonding (TAB). The bonding region 152 may be connected to a chip package or a board using flip-chip technology. As mentioned previously, the bonding region 152 may comprise an underbump metallization (UBM) layer, a redistribution layer (RDL) structure, or bonding pads to reroute peripheral pads to an area array. The bonding region 152 may further comprise a solder bump disposed thereon using a process such as screen printing and reflow, and may comprise other materials such as gold.

Accordingly, in one embodiment, a method comprises providing a multilayer interconnect structure (MLI) over a semiconductor substrate, wherein the MLI comprises a plurality of fuse connection features and a plurality of bonding connection features. A passivation layer is formed over the MLI, and the passivation layer is patterned to form a plurality of openings, each being aligned with one of the plurality of fuse connection features or one of the plurality of bonding connection features. A conductive layer is formed on the passivation layer and in the plurality of openings, and the conductive layer is patterned to form a plurality of bonding features and fuse structures, wherein each bonding feature is in contact with one of the plurality of bonding connection features, and wherein each fuse structure is in contact with two of the plurality of fuse connection features. A cap dielectric layer is formed over the plurality of fuse structures, and the cap dielectric layer is patterned to expose at least one of the bonding features while leaving the fuse structures covered.

In another embodiment, an integrated circuit comprises a multilayer interconnect structure (MLI) on a substrate, the MLI having a plurality of fuse connection features and a plurality of bonding connection features. A passivation layer overlays the MLI and has a plurality of openings, wherein each of the openings is aligned with one of the fuse connection features or one of the bonding connection features. A conductive layer overlays the passivation layer and at least partially fills the openings, the conductive layer having at least one bonding feature in contact with one of the bonding connection features, and having at least one fuse structure in contact with two of the fuse connection features. A cap dielectric layer covers the fuse structures but not the at least one bonding feature.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

What is claimed is:

1. A method comprising:
providing a multilayer interconnect structure (MLI) over a semiconductor substrate, wherein the MLI comprises a plurality of fuse connection features and a plurality of bonding connection features;
forming a passivation layer over the MLI;
patterning the passivation layer to form a plurality of openings, each being aligned with one of the plurality of fuse connection features or one of the plurality of bonding connection features;
forming a conductive layer on the passivation layer and in the plurality of openings;
patterning the conductive layer to form a plurality of bonding features and fuse structures, wherein each bonding feature is in contact with one of the plurality of bonding connection features, and wherein each fuse structure is in contact with two of the plurality of fuse connection features;
forming a cap dielectric layer over the plurality of fuse structures; and
patterning the cap dielectric layer to expose at least one of the bonding features while leaving the fuse structures covered.

2. The method of claim 1 further comprising trimming one of the plurality of fuse structures by directing a laser at the fuse structure through the cap dielectric layer.

3. The method of claim 1 wherein forming the conductive layer comprises using a material selected from the group consisting of aluminum copper, titanium nitride, titanium, chromium, gold, tungsten, and combinations thereof.

4. The method of claim 1 wherein forming the cap dielectric layer comprises forming a silicon oxide or silicon nitride.

5. The method of claim 1 wherein forming the passivation layer comprises forming a material selected from the group consisting of silicon nitride, silicon oxide, silicon oxynitride, and combinations thereof.

6. An integrated circuit comprising:
a multilayer interconnect structure (MLI) on a substrate, the MLI having a plurality of fuse connection features and a plurality of bonding connection features;
a passivation layer overlying the MLI and having a plurality of openings, wherein each of the openings is aligned with one of the fuse connection features or one of the bonding connection features;
a conductive layer overlying the passivation layer and at least partially filling the openings, the conductive layer having at least one bonding feature in contact with one of the bonding connection features, and having at least one fuse structure in contact with two of the fuse connection features; and
a cap dielectric layer covering the fuse structures but not the at least one bonding feature.

7. The integrated circuit of claim 6 wherein the fuse structure is positioned at a higher level than at least a portion of the bonding contact feature.

8. The integrated circuit of claim 6 wherein the conductive layer comprises aluminum copper alloy.

9. The integrated circuit of claim 6 wherein the conductive layer comprises a multiple-thickness structure.

10. The integrated circuit of claim 9 wherein the conductive layer comprises a redistribution layer (RDL) structure.

11. The integrated circuit of claim 6 wherein the cap dielectric layer comprises a material selected from the group consisting of silicon oxide, silicon nitride, and combinations thereof.

12. The integrated circuit of claim 6 wherein the cap dielectric layer is translucent to a laser beam used in a laser fuse repair process.

13. The integrated circuit of claim 6 wherein the cap dielectric layer seals the plurality of fuse structures from exposure to moisture.

14. The integrated circuit of claim 6 wherein at least a portion of the plurality of openings have sloped sidewalls.

15. The integrated circuit of claim 6 wherein the MLI comprises copper.

16. The integrated circuit of claim 6 further comprising a plurality of semiconductor devices disposed in the substrate and routed to the MLI.

17. The integrated circuit of claim 16 wherein the plurality of semiconductor devices comprises memory cells.
